(19) United States
(12) Patent Application Publication
(10) Pub. No.: US 2008/0151150 A1
(43) Pub. Date: Jun. 26, 2008

(54) LIQUID CRYSTAL DISPLAY PANEL AND METHOD FOR MANUFACTURING THEREOF

(76) Inventor: Seung Hee LEE, Jeonju-si (KR)

Correspondence Address: BIRCH STEWART KOLASCH & BIRCH, PO BOX 747, FALLS CHURCH, VA, 22040-0747, US

(21) Appl. No.: 11/770,557

(22) Filed: Jun. 28, 2007

(30) Foreign Application Priority Data
Dec. 26, 2006 (KR) 10-2006-0133686

(51) Int. Cl. G02F 1/1337; G02F 1/1335; H01L 21/02

(52) U.S. Cl. 349/106; 349/132; 438/30; 977/952; 257/E21.535

(57) ABSTRACT

A liquid crystal display panel for improving a response speed of a liquid crystal and a left DC using a carbon nanotube, and a fabricating method thereof are discussed. In the liquid crystal display panel according to an embodiment, a color filter substrate has first thin film patterns. A thin film transistor substrate is formed in opposition to the color filter substrate and has second thin film patterns which form a horizontal electric field. And a liquid crystal composition is injected between a cell gap formed by the two substrates and is rotated in a horizontal direction in accordance with a horizontal electric field, wherein the liquid crystal composition includes liquid crystals and carbon nanotubes which are dispersed between the liquid crystals in a predetermined quantity.

This application claims the benefit of Korean Patent Application No. 10-2006-0133686 filed in Korea on Dec. 26, 2006, which is hereby incorporated by reference.

### BACKGROUND OF THE INVENTION

1. Field of the Invention

The present invention relates to a liquid crystal display panel and a fabricating method thereof, and more particularly to a liquid crystal display panel that is adaptive for increasing a response speed of a liquid crystal and at the same time removing a left DC using a carbon nanotubes, and a fabricating method thereof.

2. Description of the Related Art

Generally, a liquid crystal display panel controls light transmittance of a liquid crystal using an electric field to display a picture. The liquid crystal display panel is largely classified into a vertical electric field applying type and a horizontal electric field applying type depending upon a direction of electric field driving the liquid crystal.

The liquid crystal display panel of vertical electric field applying type drives a liquid crystal in a Twisted Nemastic TN mode with a vertical electric field formed between a pixel electrode and a common electrode arranged in opposition to each other on upper and lower substrates. The liquid crystal display panel of vertical electric field applying type has an advantage of a large aperture ratio while having a drawback of a narrow viewing angle about 90°.

The liquid crystal display panel of horizontal electric field applying type drives a liquid crystal in an in plane switch (IPS) mode with a horizontal electric field between the pixel electrode and the common electrode arranged in parallel to each other on the lower substrate. The liquid crystal display panel of horizontal electric field applying type has an advantage of a wide viewing angle about 160°, but has a disadvantage of low aperture ratio and transmittance.

Recently, in order to overcome the disadvantage of the liquid crystal display panel of horizontal electric field applying type, there has been suggested a liquid crystal display panel of fringe field switching (FFS) type operated by a fringe field. The FFS-type liquid crystal display panel includes a common electrode and a pixel electrode having an insulating film therebetween at each pixel area, and is provided such that a distance between the common electrode plate and pixel electrodes is narrower than a distance between the upper substrate and the lower substrates, to provide a fringe field. Furthermore, the fringe field allows all of liquid crystal molecules filled between the upper and lower substrates to be operated at each pixel area to improve an aperture ratio and a transmittance.

In the above-mentioned the liquid crystal display panel of horizontal electric field applying type, a liquid crystal having a dielectric anisotropy is rotated in accordance with a horizontal electric field which is formed between the pixel electrode and the common electrode (or common electrode plate) to adjust a light transmittance, so that a gray scale of a screen is realized.

In this case, it is difficult for the liquid crystal display panel of horizontal electric field applying type to increase a response speed of the liquid crystal to have a value of more than a predetermined value. Thus, there is a problem in that a residual image of a previous screen is generated when a moving picture is displayed.

Furthermore, in the liquid crystal display panel of horizontal electric field applying type, impurity ions are left within a liquid crystal space, so that a left DC is generated. Herein, the impurity ions are generated at a surface of an alignment film when a rubbing process is carried out.

### SUMMARY OF THE INVENTION

Accordingly, it is an object of the present invention to provide a liquid crystal display panel that is adaptive for increasing a response speed of a liquid crystal using a carbon nanotube, and a fabricating method thereof.

It is another object of the present invention to provide a liquid crystal display panel that is adaptive for absorbing an impurity ion generated within a liquid crystal cell upon rubbing of an alignment film to reduce a left DC, and a fabricating method thereof.

In order to achieve these and other objects of the invention, a liquid crystal display panel according to an embodiment of the present invention comprises a color filter substrate provided with first thin film patterns; a thin film transistor substrate formed in opposition to the color filter substrate and having second thin film patterns which form a horizontal electric field; and a liquid crystal composition injected between a cell gap formed by two substrates and rotated in a horizontal direction in accordance with the horizontal electric field, and wherein the liquid crystal composition includes a liquid crystal and a carbon nanotube which is dispersed with a predetermined quantity.

A method of fabricating a liquid crystal display panel according to an embodiment of the present invention comprises forming a color filter substrate provided with first thin film patterns; forming a thin film transistor substrate provided in opposition to the color filter substrate and having second thin film patterns which form a horizontal electric field; joining the color filter substrate and the thin film transistor substrate using a sealent; and injecting a liquid crystal composition which is rotated in a horizontal direction in accordance with the horizontal electric field between a cell gap formed by the two substrates, and wherein the liquid crystal composition includes liquid crystals and carbon nanotubee which are dispersed between the liquid crystals in a predetermined quantity.

A liquid crystal display panel according to another embodiment of the present invention comprises a color filter substrate provided with first thin film patterns; a thin film transistor substrate formed in opposition to the color filter substrate and having second thin film patterns which form a fringe field; and a liquid crystal composition injected between a cell gap formed by two substrates and rotated in a horizontal direction in accordance with a fringe field, and wherein the liquid crystal composition includes liquid crystals and carbon nanotubes which are dispersed between the liquid crystals in a predetermined quantity.

In the liquid crystal display panel, a quantity of the carbon nanotube which is included in the liquid crystal composition is less than 0.001 wt %.

In the liquid crystal display panel, the carbon nanotube which is included in the liquid crystal composition has a single layer structure or a multiple layer structure.

In the liquid crystal display panel, a length of the carbon nanotube which is included in the liquid crystal composition is less than two times of a thickness of the cell gap in order to allow the liquid crystal to be rotated toward a horizontal direction in accordance with a fringe field.

A method of fabricating a liquid crystal display panel according to another embodiment of the present invention comprises forming a color filter substrate provided with first thin film patterns; forming a thin film transistor substrate provided in opposition to the color filter substrate and having second thin film patterns which form a fringe field; joining a color filter substrate and a thin film transistor substrate using a sealant; and injecting a liquid crystal composition which is rotated in a horizontal direction in accordance with the fringe field between a cell gap formed by the two substrates, and wherein the liquid crystal composition includes a liquid crystal and a carbon nanotube which is dispersed with a predetermined quantity.

In the method, a quantity of the carbon nanotube which is included in the liquid crystal composition is less than 0.001 wt %.

In the method, the carbon nanotube which is included in the liquid crystal composition has a single layer structure or a multiple layer structure.

In the method, a length of the carbon nanotube which is included in the liquid crystal composition is less than two times of a thickness of the cell gap in order to allow the liquid crystal to be rotated toward a horizontal direction in accordance with a fringe field.

### BRIEF DESCRIPTION OF THE DRAWINGS

These and other objects of the invention will be apparent from the following detailed description of the embodiments of the present invention with reference to the accompanying drawings, in which:

FIG. 1 is a sectional view showing a configuration of a liquid crystal display panel of in plane switch type according to the present invention;

FIG. 2 is a plan view showing a thin film transistor substrate comprising the liquid crystal display panel of in plane switch type according to the present invention;

FIG. 3 is a diagram broadly showing a surface of a liquid crystal composition to which a carbon nanotube is dispersed according to the present invention;

FIG. 4A and FIG. 4B are diagrams showing a configuration of a carbon nanotube which is dispersed to the liquid crystal composition according to the present invention;

FIG. 5 is a diagram showing a distribution of a left DC of a liquid crystal display panel which is formed of the liquid crystal composition according to the present invention;

FIG. 6A is a sectional view broadly showing a liquid crystal display panel to which a horizontal electric field is not applied according to the present invention;

FIG. 6B is a sectional view broadly showing a liquid crystal display panel to which a horizontal electric field is applied according to the present invention;

FIGS. 7A and 7B are graphs showing examples of a distribution of a response speed of a liquid crystal display panel which is formed of the liquid crystal composition according to the present invention;

FIG. 8 is a flow chart showing a process of a liquid crystal display panel of in plane switch IPS type according to the present invention;

FIG. 9 is a sectional view showing a configuration of a liquid crystal display panel of fringe field switching FFS type according to the present invention;

FIG. 10 is a plan view showing a thin film transistor substrate which is included in the liquid crystal display panel of fringe field switching FFS type according to the present invention;

FIG. 11A is a sectional view broadly showing a liquid crystal display panel to which a fringe field is not applied according to the preset invention;

FIG. 11B is a sectional view broadly showing a liquid crystal display panel to which a fringe field is applied according to the preset invention; and

FIG. 12 is a flow chart showing a process of a liquid crystal display panel of fringe field switching FFS type according to the present invention;

### DETAILED DESCRIPTION OF THE PREFERRED EMBODIMENTS

Hereinafter, a flat display panel and a fabricating method thereof according to various embodiments of the present invention will be described with reference to the accompanying drawings.

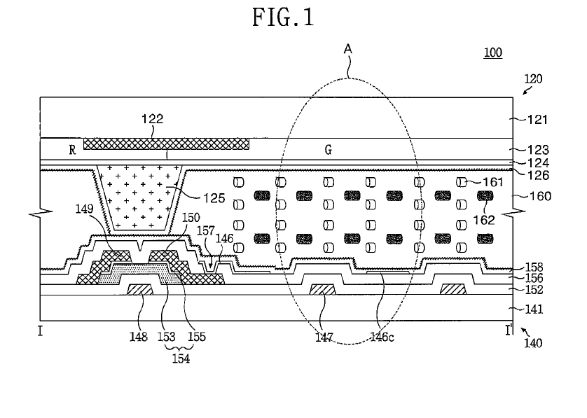

First, a horizontal electric field applying type liquid crystal display panel of in plane switch (hereinafter, referred to as “IPS”) type and a fabricating method thereof according to the present invention will be described with reference to FIG. 1 to FIG. 8.

Referring to FIG. 1, a horizontal electric field applying type liquid crystal display panel of IPS type 100 includes a color filter substrate 120 and a thin film transistor substrate 140 that are bonded in opposition to each other, and a liquid crystal composition 160 filled into a liquid crystal space where is defined by a spacer constantly maintaining a cell gap between two substrates.

In the color filter substrate 120, a black matrix 122, a color filter 123, an over-coating layer 124, a spacer 125, and an upper alignment film 126 are sequentially formed on an upper substrate 121. Herein, the black matrix 122 prevents a light leakage. The color filter 123 realizes a color. The over-coating layer 124 smoothes a step coverage which is formed by the color filter 123. The spacer 125 constantly maintains a cell gap between two substrates. The upper alignment film 126 aligns a liquid crystal composition 160 filled into a liquid crystal space where is formed by the spacer 125 to a predetermined direction.

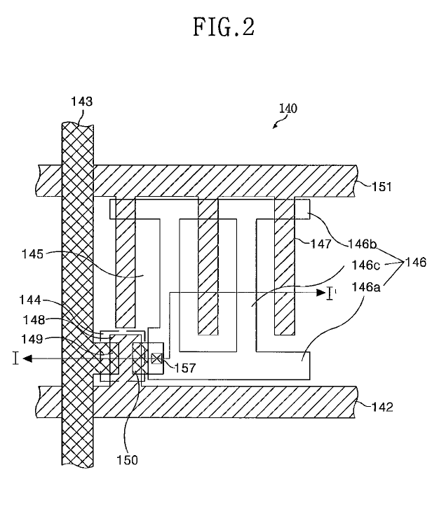

Referring to FIG. 1 and FIG. 2, the thin film transistor substrate 140 includes a plurality of signal lines and a thin film transistor 144, and a lower alignment film 158. Herein, the plurality of signal lines and the thin film transistor 144 form a horizontal electric field of a pixel unit. The lower alignment film 158 is coated on the plurality of signal lines and the thin film transistor 144 in order to align the liquid crystal composition 160.

More specifically, the thin film transistor substrate 140 includes a gate line 142 and a data line 143, the thin film transistor 144, a pixel electrode 146, a common electrode 147, and a common line 151. Herein, the gate line 142 and the data line 143 are crossed each other on the lower substrate 141. The thin film transistor 144 is formed at a crossing of the gate line 142 and the data line 143. The pixel electrode 146 and the common electrode 147 are formed to provide a horizontal electric field at a pixel area 145 where is defined by the intersection structure. Common electrodes 147 are commonly connected to the common line 151.

The gate line 142 supplies a gate signal to a gate electrode 148 of the thin film transistor 144. In this case, the gate line 142 is connected, via a gate pad part (not shown), to a gate driver (not shown).

The data line 143 supplies a pixel signal to the pixel electrode 146 via a drain electrode 150 of the thin film transistor 144. In this case, the data line 143 is connected, via a data pad part (not shown), to a data driver (not shown).

The common line 151 is formed in parallel to the gate line 142 with having the pixel area 145 therebetween, and supplies a reference voltage which drives a liquid crystal to the common electrode 147.

The thin film transistor 144 allows a pixel signal applied to the data line 143 to be charged into the pixel electrode 146 and be kept in response to a gate signal applied to the gate line 142. To this end, the thin film transistor 144 includes the gate electrode 148, a source electrode 149, and the drain electrode 150. Herein, the gate electrode 148 is connected to the gate line 142. The source electrode 149 is connected to the data line 143. The drain electrode 150 is connected to the pixel electrode 146.

Furthermore, the thin film transistor 144 further includes a semiconductor pattern 154 which has an active layer 153. Herein, the active layer 153 is overlapped with the gate electrode 148 with having a gate insulating film 152 therebetween, and forms a channel between the source electrode 149 and the drain electrode 150. The semiconductor pattern 154 further includes an ohmic contact layer 155. Herein, the ohmic contact layer 155 is located on the active layer 153 to make an ohmic contact with the data line 143, the source electrode 149, and the drain electrode 150.

The pixel electrode 146 is connected, via a contact hole 157 which is formed at a protective film 156, to the drain electrode 150 of the thin film transistor 144, and is formed at the pixel area 145. Specifically, the pixel electrode 146 includes a first horizontal part 146A, a second horizontal part 146B, and a finger part 146C. Herein, the first horizontal part 146A is connected to the drain electrode 150, and is formed in parallel to the adjacent gate line 142. The second horizontal part 146B is overlapped with the common line 151. The finger part 146C is formed in parallel to the common electrode 147 between the first horizontal part 146A and the second horizontal part 146B.

The common electrode 147 is connected to the common line 151, and is formed of the same metal as the gate line 142 and the gate electrode 148 at the pixel area 145. Specifically, the common electrode 147 is formed in parallel to the finger part 146C of the pixel electrode 146 at the pixel area 145.

Accordingly, a horizontal electric field is formed between the pixel electrode 146 and the common electrode 147. Herein, the pixel electrode 146 is supplied with a pixel signal via the thin film transistor 144. The common electrode 147 is supplied with the reference voltage via the common line 151. Specifically, a horizontal electric field is formed between the finger part 146C of the pixel electrode 146 and the common electrode 147.

The liquid crystal composition 160 is rotated due to a dielectric anisotropy. Transmittance of a light transmitting the pixel area 145 is differentiated depending upon a rotation extent of the liquid crystal composition 160 to realize an image. Herein, the liquid crystal composition 160 is arranged in a horizontal direction at a liquid crystal space between the color filter substrate 120 and the thin film transistor substrate 140 by a horizontal electric field.

The liquid crystal composition 160 has a structure that a carbon nanotube 162 of predetermined quantity, that is, less than 0.001 wt % is dispersed to a liquid crystal 161.

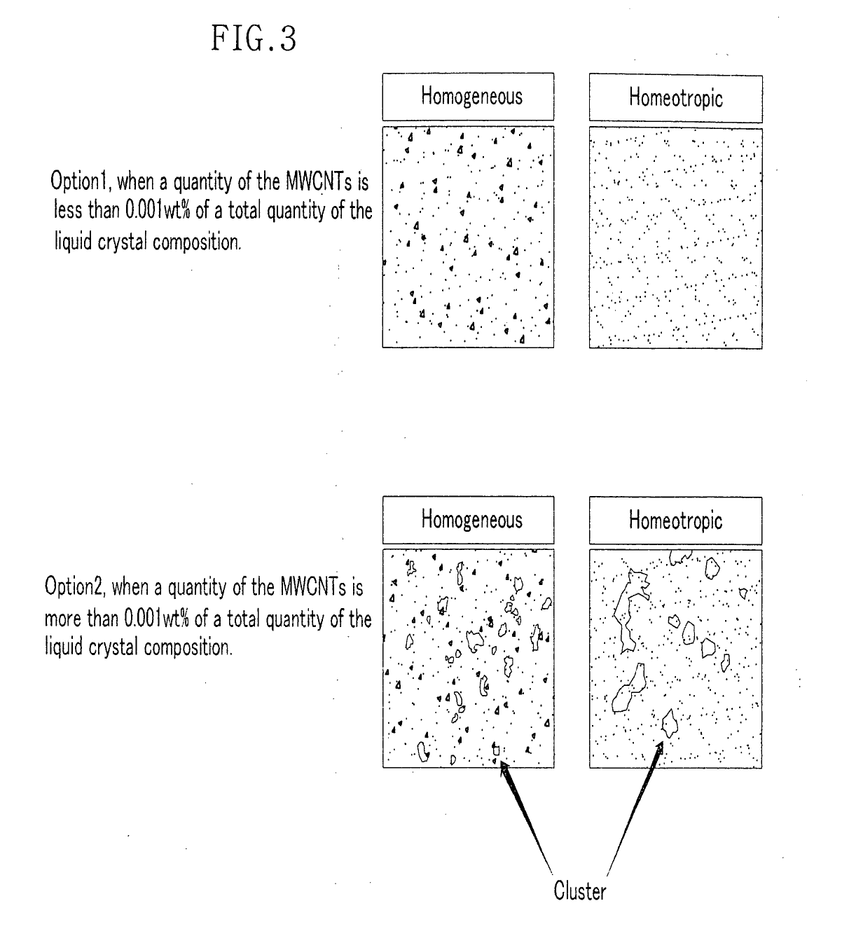

In this case, when a quantity of the carbon nanotube 162 is less than 0.001 wt %, if the liquid crystal composition 160 is aligned in a vertical direction or a horizontal direction by a horizontal electric field, a cluster of the carbon nanotube 162 is not generated as shown in FIG. 3. As a result, the liquid crystal 161 is uniformly aligned, so that a light leakage phenomenon is not generated.

However, when a quantity of the carbon nanotube 162 is more than 0.001 wt %, if the liquid crystal composition 160 is aligned in a vertical direction or a horizontal direction by a horizontal electric field, a cluster of the carbon nanotube 162 is generated. As a result, the liquid crystal 161 is aligned not to be consistent with a rubbing direction to generate a light leakage phenomenon.

Accordingly, it is desirable that a quantity of the carbon nanotube 162 is less than 0.001 wt % in order to prevent a light leakage phenomenon at a liquid crystal cell area.

The liquid crystal composition 160 is provided such that the carbon nanotube 162 having a large surface area is dispersed to the liquid crystal 161. Furthermore, the liquid crystal composition 160 plays a role to absorb an impurity ion which generates a left DC at the liquid crystal space.

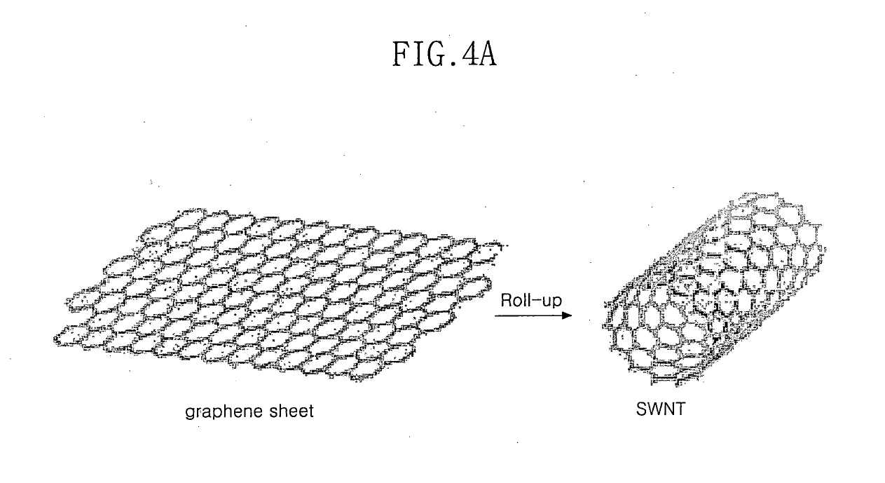

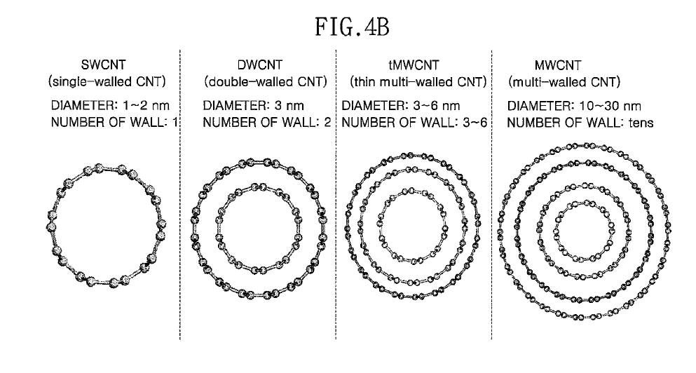

More specifically, referring to FIG. 4A, the carbon nanotube 162 has a structure that a plate structure of a carbon, that is, a graphite is rolled-up without a joint. The carbon nanotube 162 is formed of only carbon, and the inside of the carbon nanotube 162 is hollow. Furthermore, the carbon nanotube 162 has a structure that a ratio between a length (several nano meters to hundreds of nano meters) and a diameter (20 nm to 0.4 nm) is very large.

In this case, the carbon nanotube 162 is largely classified into a Single-Walled Carbon Nanotube (SWCNT), a Double-Walled Carbon Nanotube (DWCNT), a thin Multi Walled Carbon Nanotube (tMWCNT), and a Multi Walled Carbon Nanotube (MWCNT) depending upon the number of wall as shown in FIG. 4B.

Accordingly, the carbon nanotube 162 has a large surface area owing to the above-mentioned structure. Thus, the carbon nanotube 162 absorbs the impurity ion to reduce a left DC within the liquid crystal space. Herein, the impurity ion is generated at the liquid crystal space upon rubbing of the alignment film.

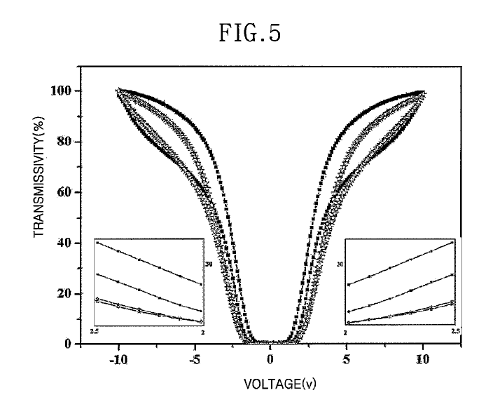

In other words, referring to FIG. 5, if a pure liquid crystal is measured at a transmittance of 10%, 50%, and 90%, a parameter which determines a picture quality of the liquid crystal display panel 100, that is, a left DC is 0.367V, 0.715V, and 3.418V, respectively. On the other hand, if the liquid crystal composition 160 to which the carbon nanotube 162 is dispersed is used, a left DC is 0.042V, 0.305V, and 1.650 V, respectively. As a result, a measured value thereof is reduced.

The liquid crystal composition 160 is rotated in accordance with a horizontal electric field which is applied between the pixel electrode 146 and the common electrode 147 to control a transmittance of an incident light, thereby realizing a gray scale of a screen.

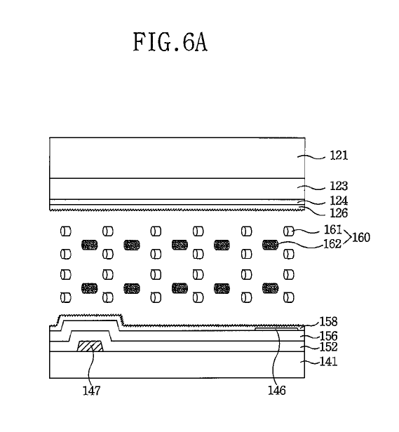

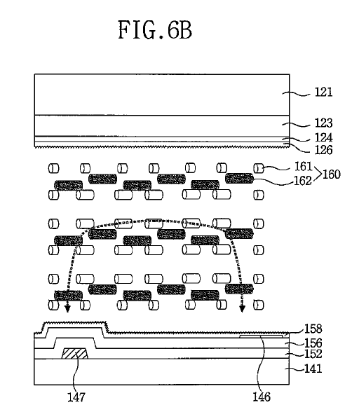

More specifically, if a horizontal electric field is not generated between the pixel electrode 146 and the common electrode 147, the liquid crystal 161 and the carbon nanotube 162 are arranged on the substrate along a rubbing direction of the alignment film as shown in FIG. 6A.

However, if a horizontal electric field is generated between the pixel electrode 146 and the common electrode 147, major axises of the liquid crystal 161 and the carbon nanotubes 162 are rotated in a direction that is parallel to a horizontal electric field as shown in FIG. 6B. Herein, it is desirable that a length of the carbon nanotubes 162 is less than two times of a cell thickness in order to facilitate a rotation of the liquid crystal 161.

In this case, the liquid crystal 161 adjacent to a surface of the alignment films 126 and 158 of the liquid crystal composition 160 is not rotated in a direction which is in parallel to a horizontal electric field and is maintained as it is by a strong surface anchoring energy.

As described above, if the liquid crystal 161 and the carbon nanotubes 162 are rotated in accordance with a horizontal electric field, a rising time of response speed parameters is reduced by maximum 20.7% and average 10.5% at a transmittance of 50% point compared to a case that a pure liquid crystal composition is used. Herein, the response speed parameters highly affect to an implementation of moving picture of the liquid crystal display panel 100. Further, a decaying time is reduced by maximum 23.8% and average 18.7% when the decaying time is measured at a transmittance of 40% point.

Accordingly, in the horizontal electric field applying type liquid crystal display panel of IPS type 100 according to the embodiment of the present invention, the liquid crystal composition 160 has a structure that the liquid crystal 161 and the carbon nanotube 162 of less than 0.001 wt % are mixed with each other to improve a response speed of the liquid crystal display panel 100 and a characteristics of a left DC.

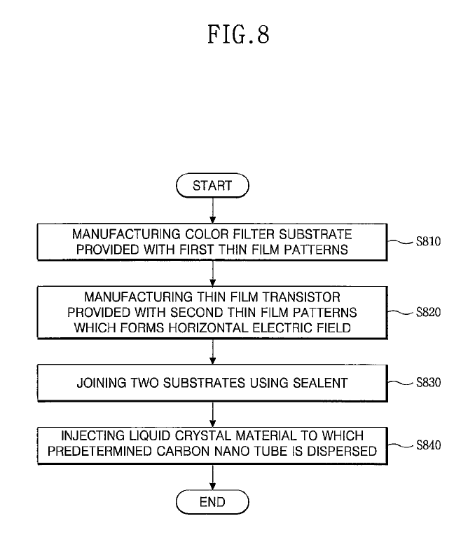

Hereinafter, a method of fabricating the horizontal electric field applying type liquid crystal display panel of IPS type according to the embodiment of the present invention will be described with reference to FIG. 8.

First, the color filter substrate 120 provided with first thin film patterns is manufactured on an upper substrate (S810).

More specifically, a step of forming the first thin film pattern of the color filter substrate 120 according to the present invention includes dividing a cell area on the upper substrate 121 and, at the same time forming the black matrix 122 which prevents a light leakage phenomenon; forming a R, G, B color filters 123 at a cell area where is divided by the black matrix 122; forming the over-coating layer 124 which is formed on the color filter 123 and compensates a step coverage; forming the spacer 125 which is formed on the over-coating layer 124 to constantly maintain a cell gap; and forming the upper alignment film 126 which is rubbed in a predetermined direction.

Next, the thin film transistor substrate 140 provided with second thin film patterns is manufactured on a lower substrate (S820). Herein, the second thin film patterns form a horizontal electric field.

More specifically, a step of forming the second thin film patterns of the thin film transistor substrate 140 according to the present invention includes forming a variety of signal lines which have the gate line 142, the data line 143, and the common line 151; forming the thin film transistor 144 which is located at an intersection area of the gate lines 142 and the data lines 143; forming the pixel electrode 146 which is connected to the drain electrode 150 of the thin film transistor 144; and forming the common electrode 147 which is connected to the common line 151 and is located in parallel to the pixel electrode 146 to provide a horizontal electric field.

Next, a sealent is coated to surround an area that an image is displayed of the liquid crystal display panel 100, and then the color filter substrate 120 provided with the first thin film patterns and the thin film transistor substrate 140 provided with the second thin film patterns are joined with each other by use of the sealent (S830).

As described above, the color filter substrate 120 and the thin film transistor substrate 140 are joined with each other by use of the sealent, and then the liquid crystal composition 160 is injected into the liquid crystal area via an injecting hole. Next, the injecting hole is sealed to complete the horizontal electric field applying type liquid crystal display panel of IPS type 100 (S640).

Herein, the liquid crystal composition 160 has a structure that the liquid crystal 161 less then 0.001 wt %, and the carbon nanotube 162 having a surface area of less then 0.001 wt % are dispersed.

In this case, the carbon nanotube 162 absorbs an impurity ion which is generated upon rubbing of the alignment films 126 and 158 to reduce a left DC which is generated at the liquid crystal space. Thus, a parameter which determines a picture quality of the liquid crystal display panel 100, that is, a left DC is reduced compared to a case that a pure liquid crystal composition is used.

Furthermore, the carbon nanotube 162 is rotated in accordance with a horizontal electric field along with the liquid crystal 161 to control a transmittance of the incident light. Thus, a rising time and a decaying time of the response speed parameters are reduced. Herein, the response speed parameters highly affect to an implementation of moving picture of the liquid crystal display panel 100. The horizontal electric field is formed between the pixel electrode 146 and the common electrode 151.

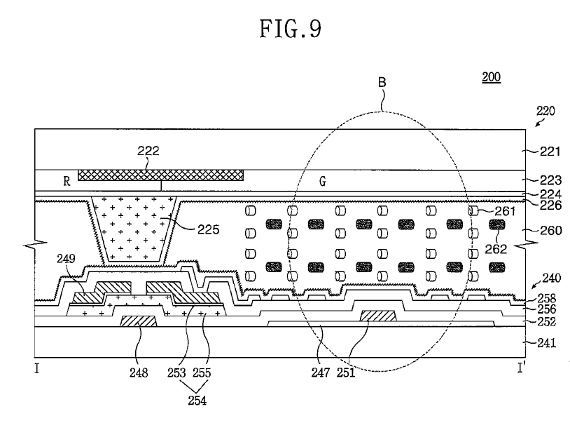

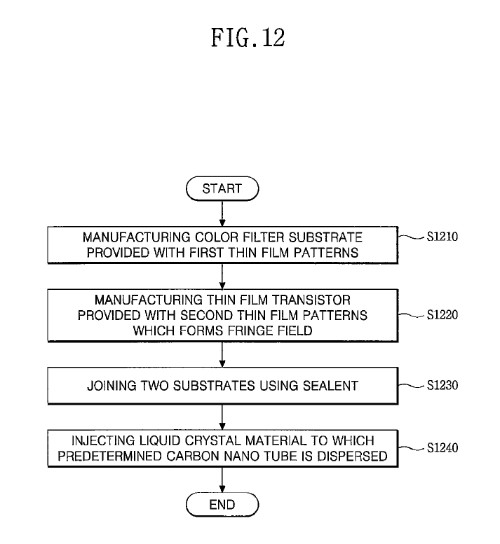

Hereinafter, a liquid crystal display panel of FFS type and a fabricating method thereof according to another embodiment of the present invention will be described with reference to FIG. 9 and FIG. 12.

The liquid crystal display panel of FFS type according to the present invention rotates the liquid crystal composition to a horizontal direction by a fringe field which is formed between the pixel electrode and the common electrode to realize a gray scale. Herein, the pixel electrode and the common electrode are overlapped with each other at each pixel area with having an insulating film therebetween.

More specifically, the liquid crystal display panel of FFS type 200 according to the present invention includes a color filter substrate 220 and a thin film transistor substrate 240, and a liquid crystal composition 260 as shown in FIG. 9. Herein, the color filter substrate 220 and the thin film transistor substrate 240 are opposed to be joined with each other. The liquid crystal composition 260 is filled into a liquid crystal space which is provided by a spacer 225. In this case, the spacer 225 constantly maintains a cell gap between two substrates.

In the color filter substrate 220, a black matrix 222, a color filter 223, an over-coating layer 224, a spacer 225, and an upper alignment film 226 are sequentially formed on an upper substrate 221. Herein, the black matrix 222 prevents a light leakage. The color filter 223 realizes a color. The over-coating layer 224 smoothes a step coverage which is formed by the color filter 223. The spacer 225 constantly maintains a cell gap between two substrates. The upper alignment film 226 aligns a liquid crystal composition 260 charged into a liquid crystal space where is formed by the spacer 225 to a predetermined direction.

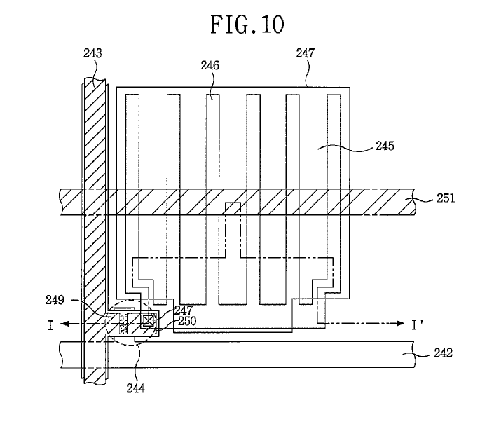

Referring to FIG. 9 and FIG. 10, a thin film transistor substrate 240 includes a gate line 242 and a data line 243, a thin film transistor 244, a common electrode plate 247 and a pixel electrode 246, and a common line 251. Herein, the gate line 242 and the data line 243 are crossed with each other on a lower substrate 241 with having a gate insulating film 252 therebetween. The thin film transistor 244 is formed at each intersection of the gate line 242 and the data line 243. The common electrode plate 247 and the pixel electrode 246 are formed to provide a fringe field at a pixel area 245 where is defined by the intersection structure with having the gate insulating film 252 and a protective film 256 therebetween. The common line 251 is connected to the common electrode plate 247.

The thin film transistor 244 allows a pixel signal applied to the data line 243 to be charged into the pixel electrode 246 and be kept in response to a gate signal applied to the gate line 242. To this end, the thin film transistor 244 includes the gate electrode 248, a source electrode 249, the drain electrode 250, and a semiconductor pattern 254. Herein, the gate electrode 248 is connected to the gate line 242. The source electrode 249 is connected to the data line 243. The drain electrode 250 is connected to the pixel electrode 246. The semiconductor pattern 254 includes an active layer 253 and an ohmic contact layer 255. Furthermore, the active layer 253 is overlapped with the gate electrode 248 with having the gate insulating film 252 therebetween, and forms a channel between the source electrode 249 and the drain electrode 250. The ohmic contact layer 255 makes an ohmic contact with the source electrode 249, the drain electrode 250, and the active layer 253.

The pixel electrode 246 is connected, via a contact hole 257 which passes through the protective film 256, to the drain electrode 250 of the thin film transistor 244 to be overlapped with the common electrode plate 247. The pixel electrode 246 and the common electrode plate 247 form a fringe field, and the liquid crystal composition 260 is rotated due to a dielectric anisotropy. Herein, the liquid crystal composition 260 is arranged in a horizontal direction between the thin film transistor substrate 240 and the color filter substrate 220. Furthermore, transmittance of a light transmitting a pixel area is differentiated depending upon a rotation extent of the liquid crystal composition 260 to realize a gray scale.

The common electrode plate 247 is formed at each pixel area, and is supplied with a reference voltage which drives a liquid crystal via the common line 251. Such a common electrode 247 is formed of a transparent conductive layer, and the common line 251 is formed of a gate metal layer along with the gate line 242.

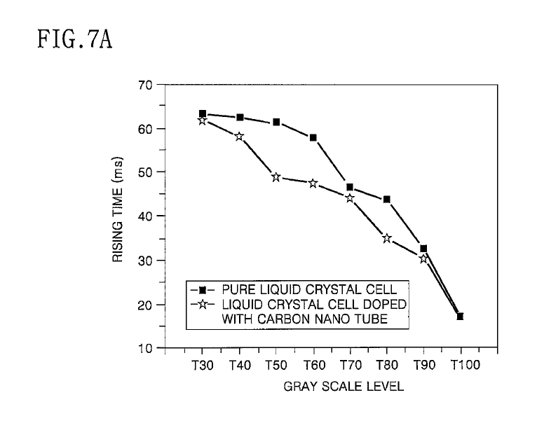

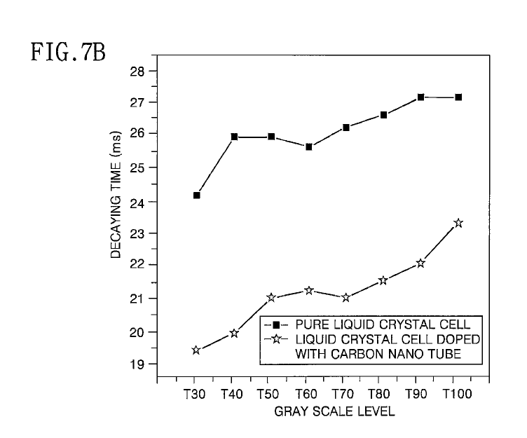

The liquid crystal composition 260 has a structure that a carbon nanotube 262 of predetermined quantity is dispersed to a liquid crystal 261. In this case, it is desirable that the carbon nanotube 262 of less than 0.001 wt % is dispersed in order not to generate a cluster as described with reference to FIGS. 7A and 7B. Herein, the cluster generates a light leakage phenomenon at a display area.

The liquid crystal composition 260 is provided such that the carbon nanotube 262 having a large surface area is dispersed to the liquid crystal 261. Thus, an impurity ion is absorbed by the carbon nanotube 262 to reduce a left DC which is generated at a liquid crystal space as described with reference to FIG. 4A and FIG. 4B. Herein, the impurity ion is generated upon rubbing of the alignment films 224 and 258.

Accordingly, the liquid crystal composition 260 is provided. As a result, a parameter which determines a picture quality of the liquid crystal display panel, that is, a left DC is reduced compared to a case that a pure liquid crystal composition is used as described with reference to FIG. 5.

The liquid crystal composition 260 is rotated in accordance with a fringe field which is formed between the pixel electrode 246 and the common electrode 247 to control a transmittance of an incident light, thereby realizing a gray scale of a screen.

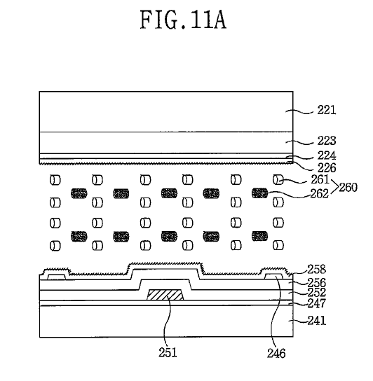

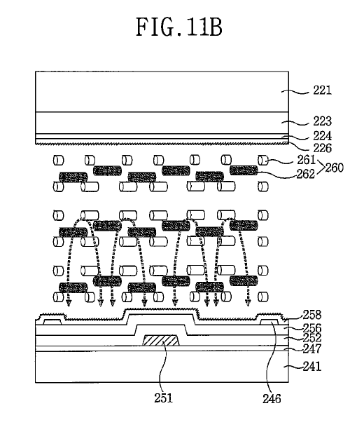

More specifically, if a fringe field is not generated between the pixel electrode 246 and the common electrode plate 247, the liquid crystal 261 and the carbon nanotube 262 are arranged on the substrate along a rubbing direction of the alignment film as shown in FIG. 11A.

However, if a fringe field is applied between the pixel electrode 246 and the common electrode plate 247, major axises of the liquid crystal 261 and the carbon nanotube 262 are rotated in a direction that is parallel to a fringe field as shown in FIG. 11B. Herein, it is desirable that a length of the carbon nanotube 262 is less than two times of a cell thickness in order to facilitate a rotation of the liquid crystal.

In this case, the liquid crystal 261 adjacent to a surface of the alignment films 226 and 258 of the liquid crystal composition 260 is not rotated in a direction which is in parallel to a fringe field and is maintained as it is by a strong surface anchoring energy.

As described above, since the liquid crystal composition 260 is formed to have a structure that the carbon nanotube 262 of less than 0.001 wt % is mixed with a liquid crystal, a rising time and a decaying time of the response speed parameters are reduced. Herein, the response speed parameters highly affect to an implementation of moving picture of the liquid crystal display panel 200 as described with reference to FIG. 7A and FIG. 7B.

Accordingly, in the horizontal electric field applying type liquid crystal display panel of FFS type according to the present invention, a liquid crystal composition is formed to have a structure that the carbon nanotube of less than 0.00.1 wt % is mixed with a liquid crystal to improve a response speed of the liquid crystal display panel and a characteristics of a left DC.

Hereinafter, a method of fabricating the horizontal electric field applying type liquid crystal display panel of FFS type according to another embodiment of the present invention will be described.

First, the color filter substrate provided with first thin film patterns is manufactured on an upper substrate as shown in FIG. 12 (S1210).

More specifically, a step of forming the first thin film pattern of the color filter substrate 220 according to the present invention includes dividing a cell area on the upper substrate 221 and, at the same time forming the black matrix 222 which prevents a light leakage phenomenon; forming a R, G, B color filters 223 at a cell area where is divided by the black matrix 222; forming the over-coating layer 224 which is formed on the color filter 223 and compensates a step coverage; forming the spacer 225 which is formed on the over-coating layer 224 to constantly maintain a cell gap; and forming the upper alignment film 226 which is rubbed in a predetermined direction.

Next, the thin film transistor substrate provided with second thin film patterns is manufactured on a lower substrate (S1220). Herein, the second thin film patterns form a fringe field.

More specifically, a step of forming the second thin film patterns of the thin film transistor substrate according to the present invention includes forming a variety of signal lines which have the gate line 242, the data line 243, and the common line 251; forming the thin film transistor 244 which is located at an intersection area of the gate lines 242 and the data lines 243; forming the pixel electrode 246 which is connected to the drain electrode 250 of the thin film transistor 244; and forming the common electrode plate 247 which is overlapped with the pixel electrode 246 at the pixel area 245 where is defined by an intersection of the gate line 242 and the data line 243 with having the gate insulting film 252 and the protective film 256 therebetween to provide a fringe field.

Next, a sealent is coated to cover an area that an image is displayed of the liquid crystal display panel 200, and then the color filter substrate 220 provided with the first thin film patterns and the thin film transistor substrate 240 provided with the second thin film patterns are joined with each other by use of the sealent (S1230).

As described above, the color filter substrate 220 and the thin film transistor substrate 240 are joined with each other by use of the sealent, and then the liquid crystal composition 260 is injected into the liquid crystal area via an injecting hole. Next, the injecting hole is sealed to complete the horizontal electric field applying type liquid crystal display panel of FFS type 200 (S1240). Herein, the liquid crystal composition 260 is rotated in a horizontal direction in accordance with a fringe field which is formed between the pixel electrode 246 and the common electrode plate 247 which is overlapped with the pixel electrode 246.

Herein, the liquid crystal composition 260 has a structure that the carbon nanotube 262 having a surface area of less then 0.001 wt % is dispersed to the liquid crystal 261.

In this case, the carbon nanotube 262 absorbs an impurity ion which is generated upon rubbing of the alignment films 226 and 258 to reduce a left DC which is generated at the liquid crystal space. Thus, a parameter which determines a picture quality of the liquid crystal display panel 200, that is, a left DC is reduced compared to a case that a pure liquid crystal composition is used.

Furthermore, the carbon nanotube 262 is rotated in accordance with a horizontal electric field along with the liquid crystal to control a transmittance of the incident light. Thus, a rising time and a decaying time of the response speed parameters are reduced. Herein, the response speed parameters highly affect to an implementation of moving picture of the liquid crystal display panel 200. The horizontal electric field is formed between the pixel electrode 246 and the common electrode 247.

As described above, the liquid crystal display panel and the fabricating method thereof according to the present invention use the liquid crystal composition having a structure that the carbon nanotube having a large surface area of less than 0.001 wt % is dispersed to improve a response speed of the liquid crystal.

Furthermore, in the present invention, the carbon nanotube absorbs an impurity ion which is generated upon rubbing of the alignment film to reduce a left DC within the liquid crystal cell which is generated by the impurity ion.

Although the present invention has been explained by the embodiments shown in the drawings described above, it should be understood to the ordinary skilled person in the art that the invention is not limited to the embodiments, but rather that various changes or modifications thereof are possible without departing from the spirit of the invention. Accordingly, the scope of the invention shall be determined only by the appended claims and their equivalents.

What is claimed is:

1. A liquid crystal display panel, comprising:
a color filter substrate provided with first thin film patterns;
a thin film transistor substrate formed in opposition to the color filter substrate and having second thin film patterns which form a horizontal electric field; and
a liquid crystal composition injected between a cell gap formed by the two substrates and rotated in a horizontal direction in accordance with the horizontal electric field, and
wherein the liquid crystal composition includes liquid crystals and carbon nanotubes which are dispersed between the liquid crystals in a predetermined quantity.

2. The liquid crystal display panel as claimed in claim 1, wherein a quantity of the carbon nanotubes is less than 0.001 wt %.

3. The liquid crystal display panel as claimed in claim 1, wherein the carbon nanotubes have a single layer structure or a multiple layer structure.

4. The liquid crystal display panel as claimed in claim 1, wherein a length of each of the carbon nanotubes is less than two times of a thickness of the cell gap in order to allow the liquid crystal to be rotated toward a horizontal direction in accordance with the horizontal electric field.

5. A method of fabricating a liquid crystal display panel, comprising:
forming a color filter substrate provided with first thin film patterns;
forming a thin film transistor substrate provided in opposition to the color filter substrate and having second thin film patterns which form a horizontal electric field;
joining the color filter substrate and the thin film transistor substrate using a sealent; and
injecting a liquid crystal composition which is rotated in a horizontal direction in accordance with the horizontal electric field between a cell gap which is provided between the two substrates, and
wherein the liquid crystal composition includes liquid crystals and carbon nanotubes dispersed between the liquid crystals in a predetermined quantity.

6. The method of fabricating the liquid crystal display panel as claimed in claim 5, wherein a quantity of the carbon nanotubes is less than 0.001 wt %.

7. The method of fabricating the liquid crystal display panel as claimed in claim 5, wherein the carbon nanotubes have a single layer structure or a multiple layer structure.

8. The method of fabricating the liquid crystal display panel as claimed in claim 5, wherein a length of each of the carbon nanotubes is less than two times of a thickness of the cell gap in order to allow the liquid crystal to be rotated toward a horizontal direction in accordance with the horizontal electric field.

9. A liquid crystal display panel, comprising:
a color filter substrate provided with first thin film patterns;
a thin film transistor substrate formed in opposition to the color filter substrate and having second thin film patterns which form a fringe field; and
a liquid crystal composition injected between a cell gap formed by the two substrates and rotated in a horizontal direction in accordance with the fringe field, and
wherein the liquid crystal composition includes liquid crystals and carbon nanotubes which are dispersed between the liquid crystals in a predetermined quantity.

10. The liquid crystal display panel as claimed in claim 9, wherein a quantity of the carbon nanotubes is less than 0.001 wt %.

11. The liquid crystal display panel as claimed in claim 9, wherein the carbon nanotubes have a single layer structure or a multiple layer structure.

12. The liquid crystal display panel as claimed in claim 9, wherein a length of each of the carbon nanotubes is less than two times of a thickness of the cell gap in order to allow the liquid crystal to be rotated toward a horizontal direction in accordance with a fringe field.

13. A method of fabricating a liquid crystal display panel, comprising:
forming a color filter substrate provided with first thin film patterns;
forming a thin film transistor substrate provided in opposition to the color filter substrate and having second thin film patterns which form a fringe field;
joining the color filter substrate and the thin film transistor substrate using a sealent; and
injecting a liquid crystal composition which is rotated in a horizontal direction in accordance with the fringe field formed in a cell gap formed by the two substrates, and
wherein the liquid crystal composition includes liquid crystals and carbon nanotubes which are dispersed between the liquid crystals in a predetermined quantity.

14. The method of fabricating the liquid crystal display panel as claimed in claim 13, wherein a quantity of the carbon nanotubes is less than 0.001 wt %.

15. The method of fabricating the liquid crystal display panel as claimed in claim 13, wherein the carbon nanotubes have a single layer structure or a multiple layer structure.

16. The method of fabricating the liquid crystal display panel as claimed in claim 13, wherein a length of each of the carbon nanotubes is less than two times of a thickness of the cell gap in order to allow the liquid crystal to be rotated toward a horizontal direction in accordance with the fringe field.
